(19) United States
(12) Patent Application Publication
(10) Pub. No.: US 2025/0157798 A1
(43) Pub. Date: May 15, 2025

(54) CONTROL PROGRAM, INFORMATION PROCESSING PROGRAM, CONTROL METHOD, INFORMATION PROCESSING METHOD, PLASMA PROCESSING DEVICE, AND INFORMATION PROCESSING DEVICE

(71) Applicant: Tokyo Electron Limited, Tokyo (JP)

(72) Inventors: Ryohei TAKEDA, Miyagi (JP); Wataru TAKAYAMA, Miyagi (JP); Muneyuki OMI, Miyagi (JP); Keita YAEGASHI, Miyagi (JP); Sho TOMINAGA, Miyagi (JP); Joji TAKAYOSHI, Miyagi (JP)

(73) Assignee: Tokyo Electron Limited, Tokyo (JP)

(21) Appl. No.: 19/021,284

(22) Filed: Jan. 15, 2025

Related U.S. Application Data
(63) Continuation of application No. PCT/JP2023/026016, filed on Jul. 14, 2023.

(30) Foreign Application Priority Data
Jul. 22, 2022 (JP) 2022-117382

(51) Int. Cl. H01J 37/32

(52) U.S. Cl. CPC H01J 37/32908; H01J 2237/002; H01J 2237/24564; H01J 2237/24585

(57) ABSTRACT

A control program for a plasma processing device that executes plasma processing by supplying source power to a plasma generation source and supplying bias power to a stage on which a substrate to be processed is placed, and the control program causes a computer to observe a peak-to-peak voltage between the source power and the bias power, and adjust the source power supplied to the plasma generation source, the bias power supplied to the stage, a direct-current voltage applied to an outer peripheral member disposed around the stage, and an impedance of a filter circuit connected between a source of the direct-current voltage and the outer peripheral member, the source power, the bias power, the direct-current voltage and the impedance being adjustment parameters for controlling a fluctuation width of the observed peak-to-peak voltage.

### CROSS-REFERENCE TO RELATED APPLICATIONS

This application is a bypass continuation application of international application No. PCT/JP2023/026016 having an international filing date of Jul. 14, 2023 and designating the United States, the international application being based upon and claiming the benefit of priority from Japanese Patent Application No. 2022-117382, filed on Jul. 22, 2022, the entire contents of each are incorporated herein by reference.

### TECHNICAL FIELD

The present disclosure relates to a control program, an information processing program, a control method, an information processing method, a plasma processing device, and an information processing device.

### BACKGROUND

A plasma processing device is used for plasma-processing a substrate. In a chamber of the plasma processing device, the substrate is disposed in a region surrounded by an outer peripheral member called an edge ring or a focus ring.

When the plasma processing is executed by the plasma processing device, the outer peripheral member is worn and a thickness thereof is reduced. As the thickness of the outer peripheral member is reduced, an upper end position of a sheath above the outer peripheral member is lowered. When the upper end position of the sheath above the outer peripheral member is lowered, ions from plasma collide with an edge of the substrate at a tilted angle. As a result, an opening formed in the edge of the substrate is tilted. PTL 1 discloses that a direct-current voltage is applied to the outer peripheral member so as to prevent tilting of the opening formed in the edge of the substrate.

### CITATION LIST

### Patent Documents

PTL 1: JP2007-258417A

### SUMMARY

The present disclosure provides a control program, a control method, and a plasma processing device that prevent deterioration of process characteristics accompanying with wear of a member disposed in a chamber and individual differences in the process characteristics of the plasma processing device.

A control program according to an embodiment of the present disclosure is for a plasma processing device that executes plasma processing by supplying source power to a plasma generation source and supplying bias power to a stage on which a substrate to be processed is placed, and the control program causes a computer to observe a peak-to-peak voltage between the source power and the bias power, and adjust the source power supplied to the plasma generation source, the bias power supplied to the stage, a direct-current voltage applied to an outer peripheral member disposed around the stage, and an impedance of a filter circuit connected between a source of the direct-current voltage and the outer peripheral member, the source power, the bias power, the direct-current voltage, and the impedance being adjustment parameters for controlling a fluctuation width of the observed peak-to-peak voltage.

According to the present disclosure, it is possible to prevent the deterioration of the process characteristics accompanying with wear of the member disposed in the chamber and the individual differences in the process characteristics of the plasma processing device.

### BRIEF DESCRIPTION OF DRAWINGS

FIG. 1 is a view for explaining an example of a configuration of a capacitively-coupled plasma processing apparatus.

FIG. 2 is a view illustrating an outline of a control method.

FIG. 3 is a view illustrating a method for adjusting parameters according to Embodiment 1.

FIG. 4 is a flowchart illustrating steps of adjusting the parameters according to Embodiment 1.

FIG. 5 is a view illustrating a method for adjusting parameters according to Embodiment 2.

FIG. 6 is a flowchart illustrating steps of adjusting parameters according to Embodiment 3.

FIG. 7 is a flowchart illustrating steps of processing executed by a controller according to Embodiment 4.

FIG. 8 is a schematic diagram illustrating a first configuration example of a plasma processing system according to Embodiment 5.

FIG. 9 is a schematic diagram illustrating a second configuration example of the plasma processing system according to Embodiment 5.

FIG. 10 is a conceptual diagram illustrating an example of a setting file.

### DETAILED DESCRIPTION

### Embodiment 1

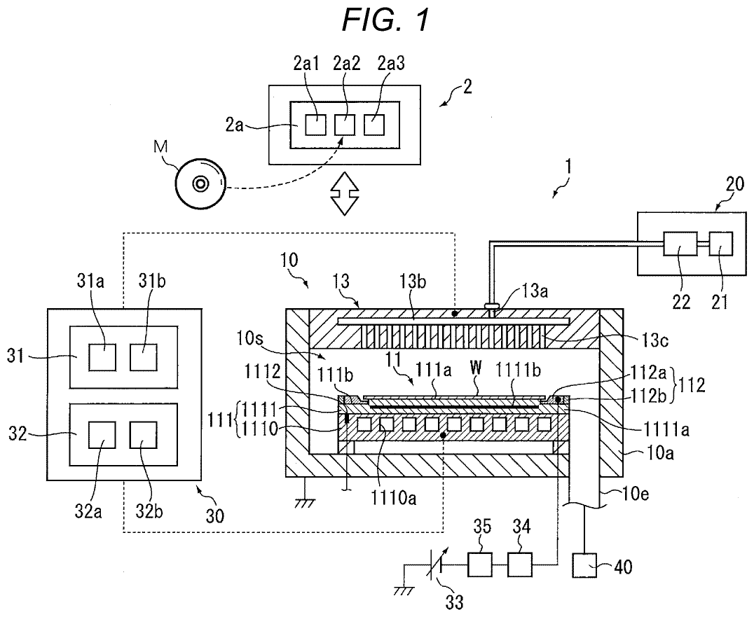

Hereinafter, a configuration example of a plasma processing system will be described. FIG. 1 is a view for explaining an example of a configuration of a capacitively-coupled plasma processing apparatus.

The plasma processing system includes a capacitively-coupled plasma processing apparatus 1 and a controller 2. The capacitively-coupled plasma processing apparatus 1 includes a plasma processing chamber 10, a gas supply 20, a power source 30, and an exhaust system 40. Further, the plasma processing apparatus 1 includes a substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a part of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 has at least one gas supply port for supplying at least one processing gas into the plasma processing space 10s, and at least one gas exhaust port for exhausting the gas from the plasma processing space. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a central region 111a for supporting a substrate W and an annular region 111b for supporting the ring assembly 112. A wafer is an example of the substrate W. The annular region 111b of the main body 111 surrounds the central region 111a of the main body 111 in a plan view. The substrate W is disposed on the central region 111a of the main body 111 and the ring assembly 112 is disposed on the annular region 1l1b of the main body 111 to surround the substrate W on the central region 111a of the main body 111. Accordingly, the central region 1l1a is also referred to as a substrate support surface for supporting the substrate W, and the annular region 111b is also referred to as a ring support surface for supporting the ring assembly 112.

In one embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In one embodiment, the ceramic member 1111a also has the annular region 111b. Other members that surround the electrostatic chuck 1111, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 1111 and the annular insulating member. Further, at least one RF/DC electrode coupled to a radio frequency (RF) power source 31 and/or a direct current (DC) power source 32 to be described below may be disposed inside the ceramic member 1111a. In this case, at least one RF/DC electrode functions as the lower electrode. In a case where the bias RF signal and/or the DC signal to be described later are supplied to at least one RF/DC electrode, the RF/DC electrode is also referred to as a bias electrode. The conductive member of the base 1110 and at least one RF/DC electrode may function as a plurality of lower electrodes. Further, the electrostatic electrode 1111b may function as the lower electrode. Accordingly, the substrate support 11 includes at least one lower electrode.

The ring assembly 112 includes one or more annular members. In one embodiment, one or more annular members include one or more edge rings and at least one cover ring. The edge ring is formed of a conductive material or an insulating material, and the cover ring is formed of an insulating material. The edge ring is also referred to as a focus ring (FR). The ring assembly 112 illustrated in FIG. 1 includes an annular edge ring 112a and an annular cover ring 112b disposed around the edge ring 112a.

Further, the substrate support 11 may include a temperature control module configured to adjust at least one of the electrostatic chuck 1111, the ring assembly 112, and the substrate to a target temperature. The temperature control module may include a heater, a heat transfer medium, a flow path 1110a, or a combination thereof. A heat transfer fluid, such as brine or gas, flows through the flow path 1110a. In one embodiment, the flow path 1110a is formed inside the base 1110, and one or more heaters are disposed in the ceramic member 1111a of the electrostatic chuck 1111. Further, the substrate support 11 may include a heat transfer gas supply configured to supply a heat transfer gas to a gap between a rear surface of the substrate W and the central region 111a. Further, a cooling medium such as cooling water may be supplied to the flow path 1110a from a chiller unit (not illustrated) provided outside the plasma processing chamber 10. At least one of the electrostatic chuck 1111, the ring assembly 112, and the substrate may be cooled to a desired temperature by adjusting a set temperature of the cooling medium circulated through the flow path 1110a. The plasma processing device 1 may include a temperature sensor 1112 that measures a temperature of the lower electrode. The controller 2 can acquire the temperature of the lower electrode measured by the temperature sensor 1112, and control a temperature control module such that the temperature of the lower electrode reaches the set temperature.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. Further, the shower head 13 includes at least one upper electrode. The gas introduction unit may include, in addition to the shower head 13, one or a plurality of side gas injectors (SGI) that are attached to one or a plurality of openings formed in the sidewall 10a.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. Each flow rate controller 22 may include, for example, a mass flow controller or a pressure-controlled flow rate controller. Further, the gas supply 20 may include one or more flow rate modulation devices that modulate or pulse flow rates of at least one processing gas.

The power source 30 includes an RF power source 31 coupled to the plasma processing chamber 10 via at least one impedance matching circuit. The RF power source 31 is configured to supply at least one RF signal (RF power) to at least one lower electrode and/or at least one upper electrode. As a result, plasma is formed from at least one processing gas supplied into the plasma processing space 10s. Accordingly, the RF power source 31 may function as at least a portion of a plasma generator configured to generate plasma from one or more processing gases in the plasma processing chamber 10. Further, supplying the bias RF signal to at least one lower electrode can generate a bias potential in the substrate W to attract an ionic component in the formed plasma to the substrate W.

In one embodiment, the RF power source 31 includes a first RF generator 31a and a second RF generator 31b. The first RF generator 31a is configured to be coupled to at least one lower electrode and/or at least one upper electrode via at least one impedance matching circuit to generate a source RF signal (source RF power) for plasma generation. In one embodiment, the source RF signal has a frequency in the range of 10 MHz to 150 MHz. In one embodiment, the first RF generator 31a may be configured to generate a plurality of source RF signals having different frequencies. The generated one or more source RF signals are supplied to at least one lower electrode and/or at least one upper electrode. Hereinafter, a peak-to-peak voltage of the source RF signal is also referred to as HF_Vpp, and source RF power (source power) is also referred to as HF_pw.

The second RF generator 31b is configured to be coupled to at least one lower electrode via at least one impedance matching circuit to generate the bias RF signal (bias RF power). A frequency of the bias RF signal may be the same as or different from a frequency of the source RF signal. In one embodiment, the bias RF signal has a lower frequency than the frequency of the source RF signal. In one embodiment, the bias RF signal has a frequency in the range of 100 kHz to 60 MHz. In one embodiment, the second RF generator 31b may be configured to generate a plurality of bias RF signals having different frequencies. The generated one or more bias RF signals are supplied to at least one lower electrode. Further, in various embodiments, at least one of the source RF signal and the bias RF signal may be pulsed. Hereinafter, a peak-to-peak voltage of the bias RF signal is also referred to as LF_Vpp, and bias RF power (bias power) is also referred to as LF_pw. The source RF power and the bias RF power are also referred to as RF_pw when there is no need to distinguish the source RF power and the bias RF power from each other.

Further, the power source 30 may include a DC power source 32 coupled to the plasma processing chamber 10. The DC power source 32 includes a first DC generator 32a and a second DC generator 32b. In one embodiment, the first DC generator 32a is configured to be connected to at least one lower electrode to generate the first DC signal. The generated first bias DC signal is applied to at least one lower electrode. In one embodiment, the second DC generator 32b is configured to be connected to at least one upper electrode to generate a second DC signal. The generated second DC signal is applied to at least one upper electrode.

In various embodiments, at least one of the first and second DC signals may be pulsed. In this case, a sequence of pulse voltages is applied to at least one lower electrode and/or at least one upper electrode. The pulse voltage may have a pulse waveform of a rectangle, a trapezoid, a triangle, or a combination thereof. In one embodiment, a waveform generator for generating a sequence of pulse voltages from the DC signal is connected between the first DC generator 32a and at least one lower electrode. Accordingly, the first DC generator 32a and the waveform generator configure a pulse voltage generator. In a case where the second DC generator 32b and the waveform generator configure the pulse voltage generator, the pulse voltage generator is connected to at least one upper electrode. The pulse voltage may have a positive polarity or a negative polarity. Further, the sequence of the pulse voltages may include one or more positive pulse voltages and one or more negative pulse voltages in one cycle. The first and second DC generators 32a and 32b may be provided in addition to the RF power source 31, and the first DC generator 32a may be provided instead of the second RF generator 31b.

The plasma processing system may further include a variable direct-current power source 33 connected to the edge ring 112a. In one embodiment, the variable direct-current power source 33 is connected to the edge ring 112a and generates a third DC signal. The generated DC signal is applied to the edge ring 112a. Hereinafter, a voltage of the third DC signal that is applied to the edge ring 112a will also be referred to as FRDC.

A first RF filter 34 and a second RF filter 35 may be connected between the edge ring 112a and the variable direct-current power source 33. The first RF filter 34 and the second RF filter 35 are filter circuits for reducing or blocking radio frequencies, and are provided to protect the variable direct-current power source 33. The first RF filter 34 reduces or blocks radio frequency (for example, 40 MHz) from the first RF generator 31a. The second RF filter 35 reduces or blocks radio frequency (for example, 400 kHz) from the second RF generator 31b.

The second RF filter 35 has a variable impedance. That is, when some elements of the second RF filter 35 are variable elements, the impedance is configured to be variable. The variable element may be, for example, either a coil (inductor) or a condenser (capacitor). Further, the present disclosure is not limited to the coil and the capacitor, and any variable impedance element such as a diode can implement the same function. The number and positions of the variable elements can also be appropriately designed by a person skilled in the art. Circuit configurations of the second RF filter 35 and the first RF filter 34 can be appropriately designed by a person skilled in the art.

The exhaust system 40 may be connected to, for example, a gas exhaust port 10e disposed at a bottom portion of the plasma processing chamber 10. The exhaust system 40 may include a pressure adjusting valve and a vacuum pump. The pressure in the plasma processing space 10s is adjusted by the pressure adjusting valve. The vacuum pump may include a turbo molecular pump, a dry pump, or a combination thereof.

The controller 2 processes computer-executable instructions for instructing the plasma processing apparatus 1 to execute various steps described herein below. The controller 2 may be configured to control the respective components of the plasma processing apparatus 1 to execute the various steps described herein below. In an embodiment, part or all of the controller 2 may be included in the plasma processing apparatus 1. The controller 2 may include a processor 2al, a storage unit 2a2, and a communication interface 2a3. The controller 2 is implemented by, for example, a computer 2a. The processor 2al may be configured to read a program from the storage unit 2a2 and perform various control operations by executing the read program. The program may be stored in advance in the storage unit 2a2, or may be acquired via a medium when necessary. The acquired program is stored in the storage unit 2a2, and is read from the storage unit 2a2 and executed by the processor 2al. The medium may be various recording media M readable by the computer 2a, or may be a communication line connected to the communication interface 2a3. The processor 2al may be a Central Processing Unit (CPU). The storage unit 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality.

As described above, the plasma processing device 1 includes various members such as the edge ring 112a, the cover ring 112b, the substrate support 11, the shower head 13 (the upper electrode), and an inner wall of the plasma processing chamber 10. These members are worn by being exposed to plasma, or are worn over time. As the members constituting the plasma processing device 1 are worn, process characteristics of the plasma processing device 1 deteriorates. Further, the plasma processing chamber 10 has individual differences (machine differences), and plasma characteristics differ among a plurality of plasma processing devices 1.

Further, in order to prevent a critical dimension (CD) abnormality or a micro under-etching, more precise control is required. In order to avoid limitation of hardware or avoid erroneous detection in an abnormality monitoring system, it is also required to reduce a parameter adjustment amount.

Therefore, the present embodiment discloses a method for adjusting a plurality of parameters in consideration of interaction among the plurality of parameters, while monitoring the peak-to-peak voltage between the source RF signal and the bias RF signal so as to prevent the deterioration of the process characteristics accompanying with wear of the members and prevent the machine difference between the chambers. In the present embodiment, it is possible to prevent the deterioration of the process characteristics accompanying with the wear of the members and eliminate the machine difference, while reducing the parameter adjustment amount.

Hereinafter, an outline of a control method will be described.

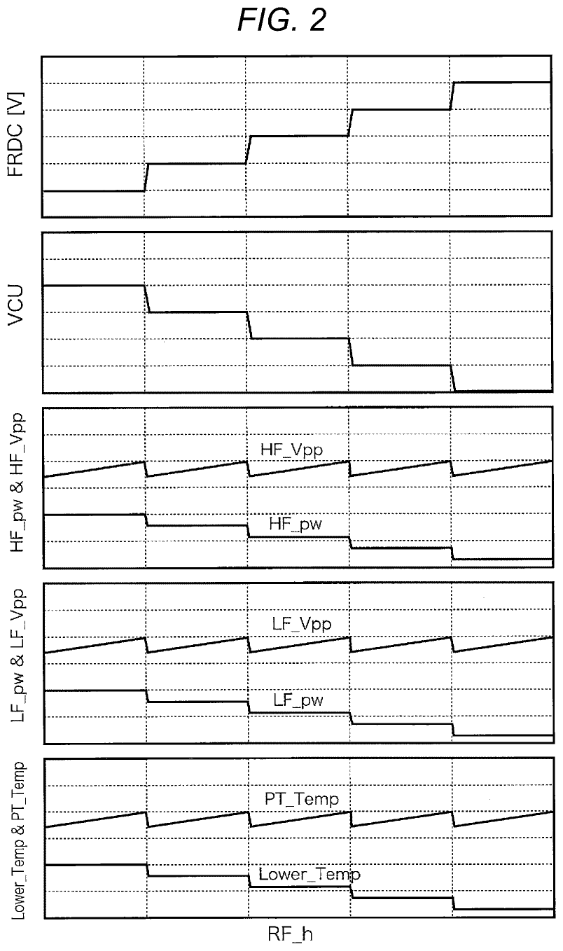

FIG. 2 is a view illustrating an outline of the control method. Each graph illustrated in FIG. 2 represents a change over time of a parameter to be adjusted. In the present embodiment, five parameters of FRDC, VCU, HF_pw, LF_pw, and Lower_Temp are adopted as parameters to be adjusted. Of the five parameters, FRDC, VCU, HF_pw, and LF_pw are parameters that interact with one another. Lower_Temp is a parameter that does not interact with other parameters to be adjusted.

The FRDC is a voltage of the third DC signal that is applied to the edge ring 112a. The controller 2 can adjust the FRDC by controlling an operation of the variable direct-current power source 33. As illustrated in the graph, the FRDC is adjusted to gradually increase according to an RF application time (RF_h). A change width ΔFRDC of the FRDC is calculated by a method to be described later.

The VCU is an impedance of the second RF filter 35. The controller 2 can adjust the VCU by controlling a capacitance value of a variable capacitor provided in the second RF filter 35. As illustrated in the graph, the VCU is adjusted to gradually decrease according to the RF application time (RF_h) while being linked to the FRDC. A change width ΔVCU of the VCU is calculated by a method to be described later. The VCU is not limited to being adjusted by the capacitance value of the variable capacitor, and may be adjusted by controlling a value of a variable inductor or a variable impedance.

The FRDC and the VCU are mainly parameters to be adjusted to prevent tilting that occurs accompanying with wear of the edge ring 112a. Since it is difficult to actually measure a wear amount of the edge ring 112a, the FRDC and the VCU are configured to change gradually according to an RF application time to prevent the occurrence of tilting in the present embodiment.

The HF_pw indicates the source RF power for generating plasma. The controller 2 can adjust the HF_pw by controlling the first RF generator 31a. The graph illustrated in FIG. 2 also illustrates a change over time of the HF_Vpp accompanying with the adjustment of the HF_pw. The HP_pw is a parameter to be adjusted together with the interacting LF_pw, FRDC, and VCU to prevent a CD fluctuation that is considered to be caused by a fluctuation of the HF_Vpp. The controller 2 learns a relationship between the four interacting parameters and the HF_Vpp in an initial stage of a process. The controller 2 adjusts each parameter with reference to the learned relationship in a subsequent process to prevent the CD fluctuation.

The LF_pw indicates the bias RF power applied to the lower electrode. The controller 2 can adjust the LF_pw by controlling an operation of the second RF generator 31b. The graph illustrated in FIG. 2 also illustrates a change over time of the LF_Vpp accompanying with the adjustment of the LF_pw. The LF_pw is a parameter to be adjusted together with the interacting HF_pw, FRDC, and VCU to prevent occurrence ofunder-etching that is considered to be caused by an increase in the LF_Vpp. The controller 2 learns a relationship between the four interacting parameters and the LF_Vpp in an initial stage of a process. The controller 2 adjusts each parameter with reference to the learned relationship in a subsequent process to prevent the occurrence of the under-etching.

The Lower_Temp is a set temperature of a cooling medium output from, for example, the chiller unit. The controller 2 can adjust the set temperature of the cooling medium by controlling the chiller unit. During the initial stage of the process, the controller 2 collects temperatures (PT_Temp) of the lower electrode measured by the temperature sensor 1112, and calculates a reference value (for example, an average value) based on the collected temperatures. When an increase in the temperature of the lower electrode is detected in a subsequent process, the controller 2 performs control to lower the set temperature of the cooling medium. Accordingly, the increase in the temperature of the lower electrode, which is considered to be one cause of the occurrence of the under-etching, is prevented.

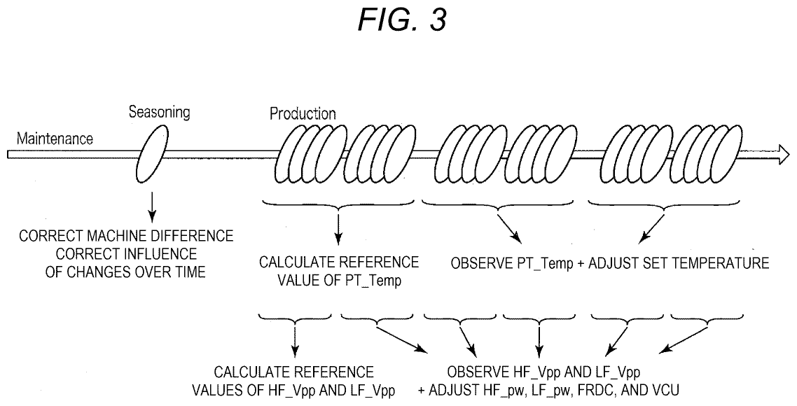

FIG. 3 is a view illustrating a method for adjusting parameters according to Embodiment 1. In the plasma processing device, in general, the inside of a processing chamber is periodically opened to the atmosphere to perform so-called wet cleaning such as replacing a member including an edge ring or removing deposits in the chamber. However, since the atmosphere in the chamber immediately after the wet cleaning is performed is different from the atmosphere during stable mass production, and as a result, plasma processing performance changes before and after the wet cleaning.

In order to solve such a problem, plasma processing (seasoning processing) that simulates plasma processing during mass production is executed after a member is replaced (or after the plasma processing device is assembled), so that a state inside the chamber approaches a state during stable mass production. In the seasoning processing, the plasma processing during mass production is often simulated by executing plasma processing using a dummy object to be processed different from an object to be processed for a product.

In the present embodiment, a specific step is inserted into the seasoning processing, and sensitivity of each parameter is obtained by performing the step. For example, during the execution of the above-described step, the controller 2 collects data of the HF_Vpp, the LF_Vpp, the HF_pw, the LF_pw, the FRDC, and the VCU, and obtains sensitivity of the HF_pw, the LF_pw, the FRDC, and the VCU relative to HF_Vpp and LF_Vpp. The controller 2 calibrates a model representing a relationship between the HF_Vpp, the LF_Vpp and the HF_pw, the LF_pw, the FRDC, the VCU based on the calculated sensitivity. By calibrating the model based on the sensitivity of the parameters, it is possible to correct variations corresponding to individual differences (machine differences) of the plasma processing chamber 10. Further, by calibrating the model, it is possible to correct an influence of a change over time on a member that is not to be replaced during maintenance, such as the electrostatic chuck 1111 and a deposition shield (not illustrated).

After the seasoning processing, the plasma processing device 1 executes plasma processing on the substrate W introduced into the plasma processing chamber 10. During the processing on the first eight substrates, the controller 2 collects data on the temperature (PT_Temp) of the lower electrode measured by the temperature sensor 1112, and calculates a reference value for the temperature of the lower electrode. An example of the reference value is an average value. Alternatively, the reference value may be other statistical measures such as a median value. Next, each time eight of the substrates W are processed, the controller 2 compares the temperature (PT_Temp) of the lower electrode measured by the temperature sensor 1112 with the reference value, and changes the set temperature (Lower_Temp) of the chiller unit when the difference therebetween exceeds a set value. For example, when a measured temperature increases by more than 0.1 degrees above the reference value, the controller 2 performs control to lower the set temperature of the chiller unit by a ×0.1 degrees. Here, a is a coefficient obtained by learning a relationship between the temperature of the lower electrode and the set temperature. The coefficient a may be a known coefficient or may be learned during the processing of the first eight substrates.

The controller 2 adjusts each parameter in parallel with the temperature control. The controller 2 collects data of the HF_Vpp and the LF_Vpp during the processing of the first four substrates (a first period), and calculates a reference value for each of the HF_Vpp and the LF_Vpp. An example of the reference value is an average value. Alternatively, the reference value may be other statistical measures such as a median value. The controller 2 calculates a difference ΔHF_Vpp between the observed HF_Vpp and the reference value and a difference ΔLF_Vpp between the observed LF_Vpp and the reference value each time the first four substrates are processed and further four of the substrates W are processed (a second period), and adjusts the HF_pw, the LF_pw, the FRDC, and the VCU using a calibrated model.

A model representing a relationship between the HF_Vpp, the LF_Vpp and the HF_pw, the LF_pw, the FRDC, the VCU can be represented by, for example, Equation 1.

$$ΔHF\_Vpp = f ( ΔHF\_pw , ΔLF\_pw , Δ FRDC , Δ VCU , α ) \qquad [ Equation 1 ]$$

$$ΔLF\_Vpp = g ( ΔHF\_pw , ΔLF\_pw , Δ FRDC , Δ VCU , β )$$

$$Δ Tilting = h ( ΔHF\_pw , ΔLF\_pw , Δ FRDC , Δ VCU , γ )$$

The model indicated by Equation 1 represents a model constructed by functions f to h. Here, the function ƒ represents a relationship among ΔHF_Vpp, a change amount (ΔHF_pw, ΔLF_pw, ΔFRDC, ΔVCU) of each parameter, and a coefficient group α. The function g represents a relationship among ΔLF_Vpp, a change amount (ΔHF_pw, ΔLF_pw, ΔFRDC, ΔVCU) of each parameter, and a coefficient group β. The function h represents a relationship among ΔTilting, a change amount (ΔHF_pw, ΔLF_pw, ΔFRDC, ΔVCU) of each parameter, and a coefficient group γ. The coefficient groups α to γ represent parameters that are calibrated in preceding seasoning processing. ΔTilting represents an amount that is temporarily determined not by observation amount but by the RF application time (RF_h).

The controller 2 can calculate an adjustment value of each parameter by calculating the change amount of each parameter based on the model indicated by Equation 1. The controller 2 adjusts the HF_pw, the LF_pw, the FRDC, and the VCU according to the calculated adjustment values. As a result, observed fluctuation widths of the HF_Vpp and the LF_Vpp are controlled.

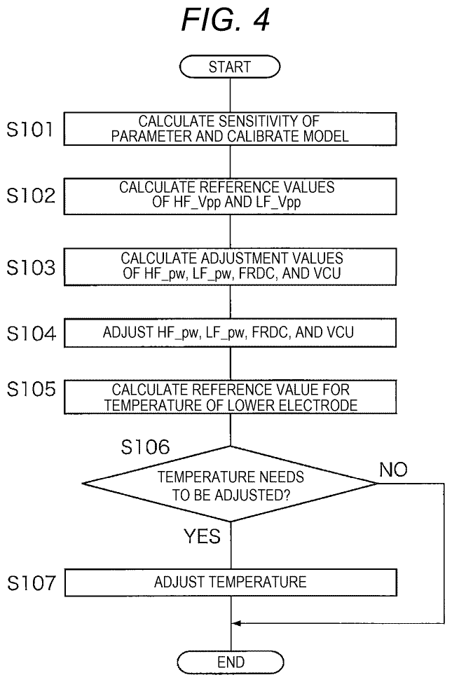

FIG. 4 is a flowchart illustrating steps of adjusting parameters according to Embodiment 1. The controller 2 collects various types of data including the above-described HF_Vpp, LF_Vpp, HF_pw, LF_pw, FRDC, VCU, and PT_Temp at any time in the seasoning processing before the start of a process or in production processing after the start of the process.

The controller 2 executes specific steps in the seasoning processing to obtain the sensitivity of a parameter, thereby calibrating the model (step S101). The controller 2 can obtain sensitivity dependent on the plasma processing chamber 10 and calibrate the model according to the sensitivity to correct individual differences (machine differences) among devices.

In the first period, the controller 2 calculates a reference value for each of the HF_Vpp and the LF_Vpp (step S102). The first period is a period during which the first four substrates W are processed in the production processing after the start of a process. The number of substrates W to be processed for defining the first period is not limited to four, and may be set as appropriate.

In the second period after the first period, the controller 2 calculates a difference ΔHF_Vpp between the HF_Vpp and the reference value and a difference ΔLF_Vpp between the LF_Vpp and the reference value, and calculates an adjustment value for each parameter of the HF_pw, the LF_pw, the FRDC, and the VCU by using the calibrated model (step S103). The second period is a repeating period that is reset each time four of the substrates W are processed after the first four substrates W are processed in the production processing. That is, the controller 2 executes step S103 each time four substrates are processed.

The controller 2 adjusts the HF_pw, the LF_pw, the FRDC, and the VCU based on the adjustment values obtained in step S103 (step S104). The controller 2 can adjust the HF_pw, the LF_pw, the FRDC, and the VCU by controlling the first RF generator 31a, the second RF generator 31b, the variable direct-current power source 33, and the second RF filter 35 according to the adjustment values.

In parallel with steps S102 to S104, the controller 2 calculates a reference value for the temperature of the lower electrode (step S105). In the production processing, for example, the controller 2 can calculate the reference value by averaging temperatures of the lower electrode collected during the processing of the first eight substrates W.

Each time subsequent four substrates W are processed, the controller 2 compares an actually measured temperature with the reference value for the temperature of the lower electrode to determine whether the temperature needs to be adjusted (step S106). For example, when the measured temperature is higher than the reference value by more than 0.1 degrees, the controller 2 determines that the temperature needs to be adjusted (S106: YES), and the controller 2 adjusts the temperature (step S107). The controller 2 adjusts the temperature by changing the set temperature of the chiller unit according to an increase amount of the temperature.

In the present embodiment, tilting caused by wear of the edge ring 112a can be prevented by autonomously adjusting the FRDC and the VCU. When only the FRDC is adjusted as a countermeasure against the tilting, it is necessary to greatly reduce the HF_pw and the LF_pw according to an increase in the FRDC. However, since the VCU is adjusted together in the present embodiment, fluctuation widths of the HF_pw and the LF_pw can be reduced. As a result, it is possible to avoid hardware limitation and avoid erroneous detection in an abnormality monitoring system.

Since the HF_pw and the LF_pw that interact with the FRDC and the VCU are adjusted autonomously in the present embodiment, the fluctuation widths of the HF_Vpp and the LF_Vpp can be reduced, and as a result, a CD fluctuation accompanying with a fluctuation of the HF_Vpp and the under-etching accompanying with an increase in the LF_Vpp can be prevented.

Since the temperature of the lower electrode is adjusted autonomously in the present embodiment, the under-etching caused by an increase in the temperature of the lower electrode can be prevented.

In Embodiment 1, the controller 2 executes correction processing. Alternatively, an external server such as a cloud server capable of communicating with the controller 2 may execute the correction processing. Further, a program installed in the controller 2 may be provided as a program product.

In Embodiment 1, the model is calibrated by embedding a specific step in the seasoning processing. Alternatively, the processing for calibrating the model may be executed separately from the seasoning processing without being embedded in the seasoning processing. Further, the processing for calibrating the model may be executed again in the production processing after the seasoning processing.

A correlation between the FRDC and the VCU may be determined in advance through analysis, and adjustment values of the FRDC and the VCU may be calculated using the correlation between the FRDC and the VCU. For example, the correlation between the FRDC and the VCU can be described as ΔFRDC=A×ΔVCU+B. Here, coefficients A and B can be uniquely determined according to the RF application time (RF_h).

A method disclosed in the present embodiment can be applied not only to prevent tilting caused by the wear of the edge ring 112a, but also to prevent deterioration of process characteristics caused by wear of any member. Further, the method disclosed in the present embodiment may be applied to prevent a change in the process characteristics accompanying with driving of the edge ring 112a. In order to prevent the tilting, the plasma processing device 1 may include a driving mechanism that drives the edge ring 112a so as to maintain heights of the substrate W and the edge ring 112a constant at all times. Since the process characteristics change accompanying with the driving of the edge ring 112a, the method disclosed in the present embodiment may be applied to prevent a change in the process characteristics.

In Embodiment 1, the HF_pw, the LF_pw, the FRDC, and the VCU are adjusted. Alternatively, in at least one of the four parameters, an adjustment value for the at least one parameter is calculated, and the at least one parameter may be adjusted based on the calculated adjustment value.

### Embodiment 2

In Embodiment 2, a configuration will be described in which adjustment of the HF_pw and the LF_pw and adjustment of the FRDC and the VCU are executed independently.

Since the configuration of the plasma processing device 1 and the configuration of the controller 2 are the same as those in Embodiment 1, descriptions thereof will be omitted.

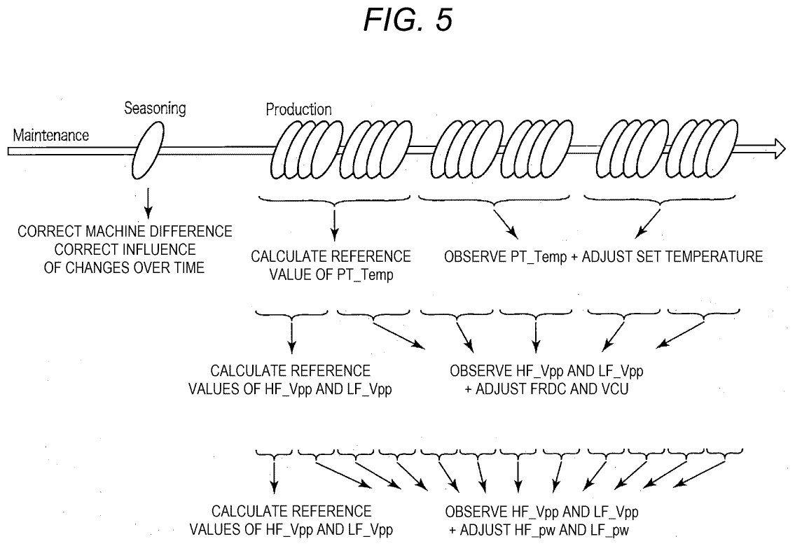

FIG. 5 is a view illustrating a method for adjusting parameters according to Embodiment 2. The controller 2 of the plasma processing device 1 executes calculation for calibrating the model in the seasoning processing before the start of a process. That is, the controller 2 obtains sensitivity of parameters dependent on the plasma processing chamber 10 and calibrates the model according to the sensitivity so as to correct individual differences (machine differences) among devices by the same steps as those in Embodiments 1.

The controller 2 controls the temperature of the lower electrode in the production processing after the start of the process. That is, the controller 2 calculates a reference value for the temperature of the lower electrode and controls the temperature of the lower electrode by adjusting the set temperature of the chiller unit according to a difference between the reference value and a measured value, by the same steps as those in Embodiment 1.

The controller 2 adjusts the FRDC and the VCU in parallel with the temperature control. The controller 2 collects data of the HF_Vpp and the LF_Vpp during the processing of the first four substrates (a first period), and calculates a reference value for each of the HF_Vpp and the LF_Vpp. An example of the reference value is an average value. Alternatively, the reference value may be other statistical measures such as a median value. The controller 2 calculates a difference ΔHF_Vpp between the observed HF_Vpp and the reference value and a difference ΔLF_Vpp between the observed LF_Vpp and the reference value each time the first four substrates are processed and further four of the substrates W are processed (a third period), and adjusts the FRDC and the VCU using the calibrated model.

Further, the controller 2 adjusts the HF_pw and the LF_pw in parallel with the temperature control. The controller 2 collects data of the HF_Vpp and the LF_Vpp during the processing of the first two substrates (a second period), and calculates a reference value for each of the HF_Vpp and the LF_Vpp. An example of the reference value is an average value. Alternatively, the reference value may be other statistical measures such as a median value. The controller 2 calculates a difference ΔHF_Vpp between the observed HF_Vpp and the reference value and a difference ΔLF_Vpp between the observed LF_Vpp and the reference value each time the first two substrates are processed and further two of the substrates W are processed (a fourth period), and adjusts the HF_pw and the LF_pw using the calibrated model. A threshold value may be provided for each of the ΔHF_Vpp and the ΔLF_Vpp, and the HF_pw and the LF_pw may be adjusted only when there is a change exceeding the threshold value. For example, when a change in the HF_Vpp is more than 1%, or when a change in the LF_Vpp is more than 4%, the HF_pw and the LF_pw may be adjusted according to the model.

In Embodiment 2, each parameter can be adjusted by a relatively simple calculation of two parameters at a time without performing a complicated calculation that includes four adjustment parameters (HF_pw, LF_pw, FRDC, and VCU). Further, it is possible to avoid concentration of a calculation load at a predetermined timing by making a timing for adjusting the HF_pw and the LF_pw different from a timing for adjusting the FRDC and the VCU.

### Embodiment 3

In the plasma processing device 1 according to Embodiment 3, a direct-current pulse voltage FR_V is applied to the edge ring 112a instead of the FRDC, and a direct-current pulse voltage Wafer_V is applied to the substrate W. In such a plasma processing device 1, a value Wafer_Cur of a current flowing through the substrate W may be monitored, and values of the direct-current pulse voltage FR_V and the direct-current pulse voltage Wafer_V applied respectively to the edge ring 12a and the substrate W may be adjusted.

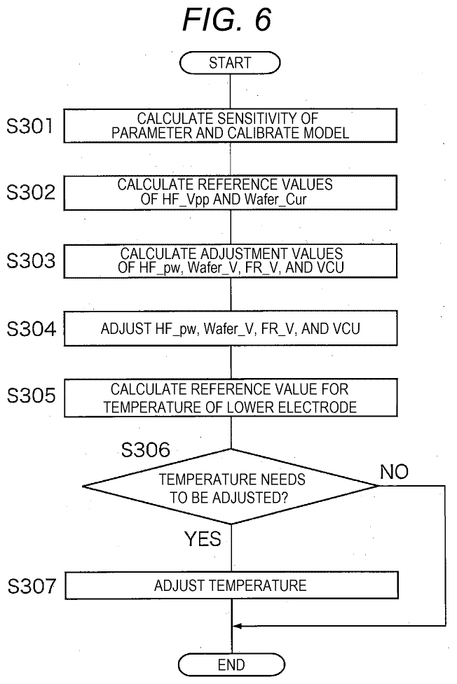

FIG. 6 is a flowchart illustrating steps of adjusting parameters in Embodiment 3. The controller 2 collects various types of data including the HF_Vpp, the Wafer_Cur, the HF_pw, the Wafer_V, the FR_V, the VCU, and the PT_Temp at any time in the seasoning processing before the start of the process or in the production processing after the start of the process.

The controller 2 executes a specific step in the seasoning processing to obtain the sensitivity of a parameter, thereby calibrating the model (step S301). The controller 2 can obtain sensitivity dependent on the plasma processing chamber 10 and calibrate the model according to the sensitivity to correct individual differences (machine differences) among devices. An equation obtained by replacing the ΔLF_Vpp with ΔWafer_Cur, replacing the ΔLF_pw with ΔWafer_V, and replacing the ΔFRDC with ΔFR_V in Equation 1 can be used as a model equation.

The controller 2 calculates a reference value for each of the HF_Vpp and the wafer_Cur in a first period (step S302). The first period is a period during which the first four substrates W are processed in the production processing after the start of a process. The number of substrates W to be processed for defining the first period is not limited to four, and may be set as appropriate. In the first period, the controller 2 can calculate the reference value by collecting values of the HF_Vpp and the Wafer_Cur and calculating an average value, a median value, a moving average value, and the like.

In a second period after the first period, the controller 2 calculates a difference ΔHF_Vpp between the HF_Vpp and the reference value and a difference ΔWafer between the Wafer_Cur and the reference value, and calculates an adjustment value for each parameter of the HF_pw, the Wafer_V, the FR_V, and the VCU by using the calibrated model (step S303). The second period is a repeating period that is reset each time four of the substrates W are processed after the first four substrates W are processed in the production processing. That is, the controller 2 executes step S303 each time four substrates are processed.

The controller 2 adjusts the HF_pw, the Wafer_Cur, the FR_V, and the VCU based on the adjustment value obtained in step S303 (step S304). The controller 2 can adjust the HF_pw, the Wafer_Cur, the FR_V, and the VCU by controlling the first RF generator 31a, a direct-current pulse power source (not illustrated), and the second RF filter 35 according to the adjustment value.

In parallel with steps S302 to S304, the controller 2 calculates a reference value for the temperature of the lower electrode (step S305). In the production processing, for example, the controller 2 can calculate the reference value by averaging temperatures of the lower electrode collected during the processing of the first eight substrates W.

Each time subsequent four substrates W are processed, the controller 2 compares an actually measured temperature with the reference value for the temperature of the lower electrode to determine whether the temperature needs to be adjusted (step S306). For example, when the measured temperature is higher than the reference value by more than 0.1 degrees, the controller 2 determines that the temperature needs to be adjusted (S306: YES), and the controller 2 adjusts the temperature (step S307). The controller 2 adjusts the temperature by changing the set temperature of the chiller unit according to an increase amount of the temperature.

In the present embodiment, tilting caused by wear of the edge ring 112a can be prevented by autonomously adjusting the FR_V and the VCU. In the present embodiment, since the VCU is adjusted together with the FR_V, fluctuation widths of the HF_pw and the Wafer_V can be reduced. As a result, it is possible to avoid hardware limitation and avoid erroneous detection in an abnormality monitoring system.

### Embodiment 4

In Embodiment 4, an interlock function will be described.

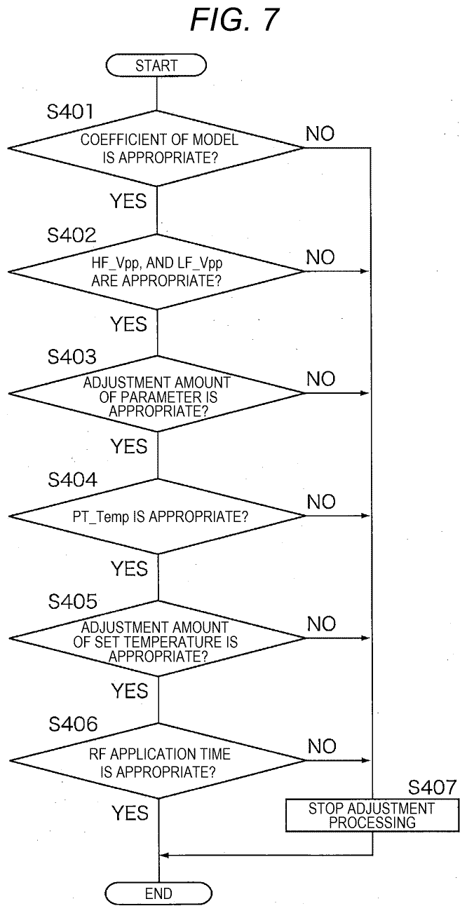

The controller 2 according to Embodiment 4 stops parameter adjustment processing when an abnormal value is found through calculation performed for adjusting each parameter. FIG. 7 is a flowchart illustrating steps of processing executed by the controller 2 according to Embodiment 4. The controller 2 determines whether a coefficient obtained by model calibration is appropriate (step S401). When a difference from a previously calculated coefficient is a threshold value or less, the controller 2 determines that the coefficient is appropriate. When it is determined that the coefficient is not appropriate (step S401: NO), the controller 2 stops the parameter adjustment processing (step S407).

The controller 2 determines whether the observed HF_Vpp and LF_Vpp are appropriate (step S402). When a difference from a previous value is, for example, 2% or less, the controller 2 determines that the HF_Vpp and the LF_Vpp are appropriate. When it is determined that the HF_Vpp and the LF_Vpp are not appropriate (step S402: NO), the controller 2 stops the parameter adjustment processing (step S407).

The controller 2 determines whether a calculated adjustment amount of a parameter is appropriate (step S403). When the calculated adjustment amount of each parameter is, for example, 3% or less of a current value, the controller 2 determines that the adjustment amount is appropriate. When it is determined that the calculated adjustment amount of any one parameter is not appropriate (step S403: NO), the controller 2 stops the parameter adjustment processing (step S407).

The controller 2 determines whether the measured PT_Temp is appropriate (step S404). When a difference from a previous value is, for example, 2 degrees or less, the controller 2 determines that the PT_Temp is appropriate. When it is determined that PT_Temp is not appropriate (step S404: NO), the controller 2 stops the parameter adjustment processing (step S407).

The controller 2 determines whether the calculated adjustment amount for the set temperature of the chiller unit is appropriate (step S405). When the calculated adjustment amount is 0.5 degrees or less, the controller 2 determines that the adjustment amount is appropriate. When it is determined that the calculated adjustment amount is not appropriate (step S405: NO), the controller 2 stops the parameter adjustment processing (step S407).

The controller 2 determines whether the RF application time is appropriate (step S406). When the RF application time is, for example, less than 600 hours, the controller 2 determines that the RF application time is appropriate. Further, when a maintenance counter increases despite the start of the production processing, it may be determined that the RF application time is not appropriate. When it is determined that the RF application time is not appropriate (step S406: NO), the controller 2 stops the parameter adjustment processing (step S407).

The order of steps S401 to S406 illustrated in the flowchart of FIG. 7 is merely an example, and each determination may be executed in an appropriate order and at an appropriate timing. In step S402, it is determined whether the HF_Vpp and the LF_Vpp are appropriate. Alternatively, when a monitoring target is the HF_Vpp and the Wafer_Cur, it may be determined whether the HF_Vpp and the Wafer_Cur are appropriate.

As described above, since the interlock function is provided in Embodiment 4, it is possible to prevent abnormal values of various parameters and adjustment amounts.

### Embodiment 5

In Embodiment 5, a configuration will be described in which an external server device connected to the controller 2 in a communicable manner calculates a parameter to be adjusted.

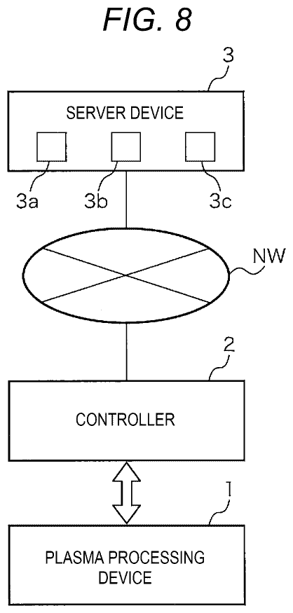

FIG. 8 is a schematic diagram illustrating a first configuration example of a plasma processing system according to Embodiment 5. The plasma processing system in Embodiment includes the plasma processing device 1, the controller 2, and a server device 3. The configurations of the plasma processing device 1 and the controller 2 are the same as those in Embodiment 1, and thus descriptions thereof will be omitted.

The server device 3 is an information processing device (computer) communicably connected to the controller 2 via a communication network NW, and the server device 3 includes a processor 3a, a storage unit 3b, a communication unit 3c, and the like. The processor 3a includes a CPU, a ROM, a RAM, and the like. The processor 3a acquires data including the HF_Vpp and the LF_Vpp, and calculates an adjustment value for each parameter of the HF_pw, the LF_pw, the FRDC, and the VCU based on the acquired data. The storage unit 3b includes a storage device such as an HDD and an SDD, and stores various computer programs to be executed by the processor 3a and data used when the various computer programs are executed. The communication unit 3c includes a communication interface for communicating with the plasma processing device 1 and the controller 2 via the communication network NW.

The data of the HF_Vpp and the LF_Vpp acquired by the processor 3a may be data observed by the plasma processing device 1 or data generated by a simulator. In the former case, the processor 3a may communicate with the plasma processing device 1 through the communication unit 3c to acquire the data observed by the plasma processing device 1. In the latter case, the processor 3a may perform a virtual experiment using a simulator to acquire data generated as a result of the virtual experiment.

For example, each time the plasma processing device 1 processes four substrates, the processor 3a of the server device 3 acquires the data of the HF_Vpp and the LF_Vpp. The processor 3a may request the controller 2 to transmit the data, and receive the data transmitted from the controller 2 as a response. Alternatively, the processor 3a may simulate processing in the plasma processing device 1 by using a simulator to acquire the data of the HF_Vpp and the LF_Vpp.

When the data of the HF_Vpp and the LF_Vpp is acquired, the processor 3a calculates the difference ΔHF_Vpp between the HF_Vpp and the reference value and the difference ΔLF_Vpp between the LF_Vpp and the reference value, and calculates an adjustment value for each parameter of the HF_pw, the LF_pw, the FRDC, and the VCU by using the model illustrated in Equation 1 or the calibrated model. Since a calculation method of the adjustment value is the same as that in Embodiments 1 to 3, detailed description thereof will be omitted.

The processor 3a of the server device 3 causes the communication unit 3c to transmit the calculated adjustment value and provides the adjustment value to the controller 2. The controller 2 adjusts the HF_pw, the LF_pw, the FRDC, and the VCU based on the adjustment value provided from the server device 3. The controller 2 adjusts the HF_pw, the LF_pw, the FRDC, and the VCU by controlling the first RF generator 31a, the second RF generator 31b, the variable direct-current power source 33, and the second RF filter 35 in the plasma processing device 1 according to each adjustment value. The controller 2 may adjust the temperature of the chiller unit after adjusting the above parameters.

As described above, in Embodiment 5, the server device 3 communicatively connected to the controller 2 can calculate an adjustment value for each parameter, and adjust the parameter in the plasma processing device 1 through the controller 2.

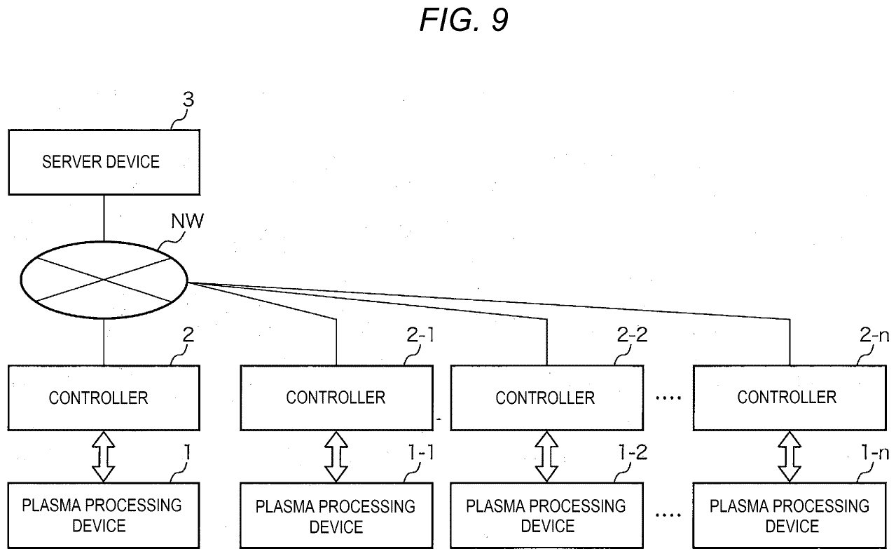

FIG. 9 is a schematic diagram illustrating a second configuration example of the plasma processing system according to Embodiment 5. In addition to the plasma processing device 1, the controller 2, and the server device 3 described above, the plasma processing system in Embodiment 5 includes plasma processing devices 1-1, 1-2, . . . 1-n, and controllers 2-1, 2-2, . . . 2-n. The controllers 2-1, 2-2, . . . 2-n control operations of the plasma processing devices 1-1, 1-2, . . . 1-n, and are connected to the communication network NW.

For example, each time the plasma processing device 1 processes four substrates, the server device 3 acquires the data of the HF_Vpp and the LF_Vpp. Alternatively, the processor 3a acquires the data of the HF_Vpp and the LF_Vpp by simulating the processing of the plasma processing device 1 by using a simulator. The processor 3a calculates the difference ΔHF_Vpp between the acquired HF_Vpp and the reference value and the difference ΔLF_Vpp between the acquired LF_Vpp and the reference value, and calculates an adjustment value for each parameter of the HF_pw, the LF_pw, the FRDC, and the VCU by using the model illustrated in Equation 1 or the calibrated model.

The server device 3 transmits a calculated parameter to the controller 2 that controls the plasma processing device 1, and transmits the calculated parameter to the controllers 2-1, 2-2, . . . 2-n that control the plasma processing devices 1-1, 1-2, . . . 1-n. The controller 2 adjusts the HF_pw, the LF_pw, the FRDC, and the VCU by controlling the first RF generator 31a, the second RF generator 31b, the variable direct-current power source 33, and the second RF filter in the plasma processing device 1 based on the adjustment value received from the server device 3. Similarly, the controllers 2-1, 2-2, . . . 2-n adjust the HF_pw, the LF_pw, FRDC, and the VCU by controlling the first RF generators, the second RF generators, the variable direct-current power sources, and the second RF filters respectively provided in the plasma processing devices 1-1, 1-2, . . . 1-n.

As described above, in the second configuration example, the adjustment value of a parameter to be applied to the plasma processing device 1 is calculated by the server device 3, and is transmitted to the controllers 2, 2-1, 2-2, . . . 2-n, so that parameters can be adjusted in the plasma processing devices 1, 1-1, 1-2, . . . 1-n.

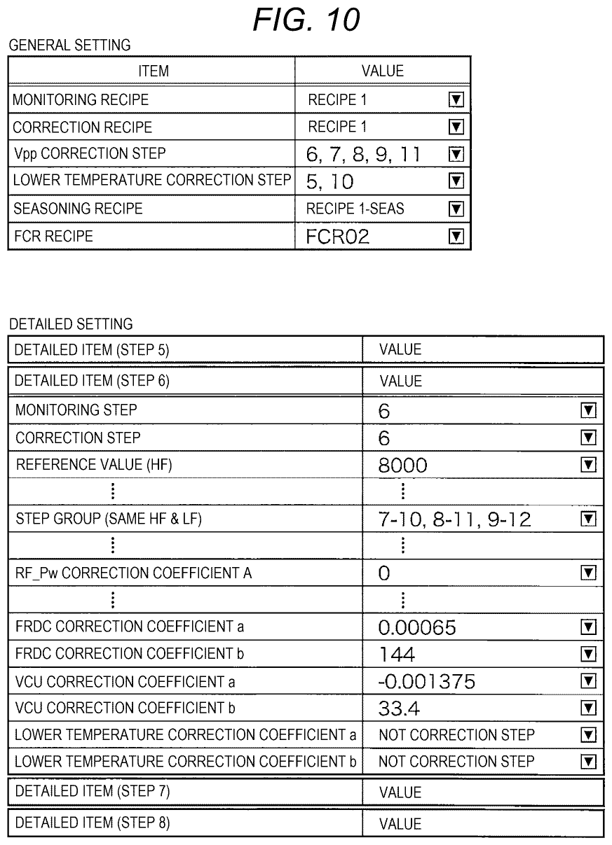

In the representative plasma processing device 1, a setting file for setting a recipe to be monitored or recording an adjustment value for each parameter may be prepared. FIG. 10 is a conceptual diagram illustrating an example of the setting file. The controller 2 of the plasma processing device 1 causes a monitor of the computer 2a to display a graphical user interface (GUI) screen as illustrated in FIG. 10, and receives an input to the setting file through an input interface such as a keyboard or a mouse provided in the computer 2a. The setting file includes a general setting and a detailed setting. In the general setting, designations of a recipe to be monitored, a recipe for which an adjustment value (correction coefficient) is to be calculated, a step, and the like are received. In the detailed setting, an initial value and the like for the correction coefficient of each parameter is received.

After the setting file is created, the representative plasma processing device 1 implements each step of the recipe (for example, seasoning recipe) designated in the setting file. The controller 2 acquires data obtained in each step, and calculates adjustment values (correction coefficients) for the HF_pw, the LF_pw, the FRDC, and the VCU. The method disclosed in Embodiments 1 to 3 is used for calculating the adjustment values. The controller 2 updates a corresponding item in the setting file based on a calculation result of the adjustment value. The controller 2 executes a series of steps designated by the setting file, and uploads the setting file obtained by updating the adjustment values (correction coefficients) of each step to the server device 3 as a template.

The server device 3 receives the setting file uploaded from the representative plasma processing device 1 through the communication unit 3c and stores the setting file in the storage unit 3b. The processor 3a of the server device 3 edits the setting file (template) stored in the storage unit 3b for the other plasma processing devices 1-1, 1-2, . . . 1-n. For example, the processor 3a edits the template to disclose only information necessary for the other plasma processing devices 1-1, 1-2, . . . 1-n. When a request is received from each of the plasma processing devices 1-1, 1-2, . . . 1-n, the processor 3a transmits the setting file edited for each device to each of the plasma processing devices 1-1, 1-2, . . . 1-n.

Each of the plasma processing devices 1-1, 1-2, . . . 1-n receives the setting file transmitted from the server device 3, and performs setting based on the setting file at an appropriate timing (timing when plasma processing is not executed).

As described above, since the setting file created in the representative plasma processing device 1 can be distributed to and adjusted for the other plasma processing devices 1-1, 1-2, . . . 1-n, it is not necessary to collect data or calculate adjustment values in each of the plasma processing devices 1-1, 1-2, . . . 1-n, and a work load on a user can be reduced.

The server device 3 may periodically collect correction coefficients and correction results that are appropriately updated in the representative plasma processing device 1 for the purpose of analyzing a cause of the occurrence of a trouble or for the purpose of collecting normal threshold values as pick data.

In Embodiment 5, the HF_pw, the LF_pw, the FRDC, and the VCU are adjusted. Alternatively, at least one of the four parameters may be adjusted by calculating an adjustment value for the at least one parameter and adjusting the at least one parameter based on the calculated adjustment value.

The embodiments disclosed herein are exemplary in all respects and are required to be considered to be not restrictive embodiments. The scope of the present invention is indicated by the scope of the claims, not the meaning described above, and is intended to include meanings equivalent to the scope of the claims and all changes within the scope.

Although an example is described in the above embodiments in which the present disclosure is applied to the capacitively-coupled plasma processing device 1, the present disclosure is not limited to the capacitively-coupled plasma processing device 1, and can be applied to a plasma processing device of any type such as an inductively coupled plasma (ICP), a radial line slot antenna (RLSA), an electron cyclotron resonance plasma (ECR), and a helicon wave plasma (HWP).

Although the wafer W is described as an example of the substrate to be processed in the embodiments described above, the substrate to be processed is not limited to the wafer W, and may be various types of substrates, printed substrates, or the like used for flat panel display (FPD).

The features described in each embodiment can be combined with each other. In addition, the independent and dependent claims set forth in the claims can be combined with each other in any and all combinations, regardless of the reciting format. Furthermore, the claims use a format of describing claims that recite two or more other claims (multi-claim format). However, the present disclosure is not limited thereto. The claims may also be described using a format of multi-claims reciting at least one multi-claim (multi-multi claims).

1. A non-transitory computer readable medium for a plasma processing device that executes plasma processing by supplying source power to a plasma generation source and supplying bias power to a stage on which a substrate to be processed is placed, the non-transitory computer readable medium including a control program in the form of computer executable program code for causing a computer to perform the following method:
observing a peak-to-peak voltage between the source power and the bias power; and
adjusting
the source power supplied to the plasma generation source,
the bias power supplied to the stage,
a direct-current voltage applied to an outer peripheral member disposed around the stage, and
an impedance of a filter circuit connected between a source of the direct-current voltage and the outer peripheral member, the source power, the bias power, the direct-current voltage and the impedance being adjustment parameters for controlling a fluctuation width of the observed peak-to-peak voltage.

2. The non-transitory computer readable medium according to claim 1, wherein the method further comprises
causing the computer to collectively adjust the source power, the bias power, the direct-current voltage, and the impedance.

3. The non-transitory computer readable medium according to claim 1, further comprising
instructing the computer to adjust the source power and the bias power independently of adjusting the direct-current voltage and the impedance.

4. The non-transitory computer readable medium according to claim 1, wherein the method further comprises:
observing a temperature of the stage; and
adjusting adjust a set temperature of a cooling medium for cooling the stage according to the observed temperature of the stage.

5. The non-transitory computer readable medium according to claim 1, wherein the method further comprises:
collecting observed values of the peak-to-peak voltage and the adjustment parameters in seasoning processing executed after the plasma processing device is assembled or after a component including the outer peripheral member is replaced; and
calibrating a model representing a relationship between the peak-to-peak voltage and the adjustment parameters based on the collected observed values,
wherein the seasoning processing involves simulating plasma processing.

6. The non-transitory computer readable medium according to claim 5, wherein the method further comprises:
calculating a reference value of the peak-to-peak voltage based on the peak-to-peak voltage observed in a first period in production processing executed after the seasoning processing, and
adjusting the adjustment parameters using the calibrated model based on a difference between the calculated reference value and the peak-to-peak voltage observed in a second period after the first period.

7. The non-transitory computer readable medium according to claim 6, wherein the method further comprises:
calculating a first reference value of the peak-to-peak voltage based on the peak-to-peak voltage observed in the first period and calculate a second reference value of the peak-to-peak voltage based on the peak-to-peak voltage observed in the second period set independently of the first period, in the production processing executed after the seasoning processing,
adjusting the direct-current voltage and the impedance using the calibrated model based on a difference between the calculated first reference value and the peak-to-peak voltage observed in a third period after the first period, and
adjusting the source power and the bias power using the calibrated model based on a difference between the calculated second reference value and the peak-to-peak voltage observed in a fourth period after the second period.

8. The non-transitory computer readable medium according to claim 1, wherein the method further comprises causing the application of a direct-current pulse voltage to the stage,
observing a value of a current flowing through the stage, and
adjusting a parameter including the direct-current pulse voltage as the adjustment parameters.

9. The non-transitory computer readable medium according to claim 1, wherein the method further comprises:
outputting data including adjusted parameters to an outside.

10. A non-transitory computer readable medium for a plasma processing device that executes plasma processing by supplying source power to a plasma generation source and supplying bias power to a stage on which a substrate to be processed is placed, the non-transitory computer readable medium including a control program in the form of computer executable program code for causing a computer to:
observe a peak-to-peak voltage between the source power and the bias power; and
adjust at least one selected from the following group:
the source power supplied to the plasma generation source,
the bias power supplied to the stage,
a direct-current voltage applied to an outer peripheral member disposed around the stage, and
an impedance of a filter circuit connected between a source of the direct-current voltage and the outer peripheral member, the at least one selected from the group being an adjustment parameter for controlling a fluctuation width of the observed peak-to-peak voltage.

11. A non-transitory computer readable medium comprising computer executable program code configured to instruct a computer to perform the following method:
acquiring data indicating a peak-to-peak voltage between a source power supplied to a plasma generation source of a plasma processing device and a bias power supplied to a stage on which a substrate to be processed is placed;
calculating at least one parameter selected from the following group:
the source power supplied to the plasma generation source,
the bias power supplied to the stage,
a direct-current voltage applied to an outer peripheral member disposed around the stage, and
an impedance of a filter circuit connected between a source of the direct-current voltage and the outer peripheral member, the at least one parameter being a parameter for controlling a fluctuation width of the peak-to-peak voltage based on the acquired data; and
outputting data including the calculated parameter.

12. A control method for a plasma processing device that executes plasma processing by supplying source power to a plasma generation source and supplying bias power to a stage on which a substrate to be processed is placed, the control method comprising a controller having a processor and a memory with a computer readable program stored therein that upon execution of the computer readable program by the processor configures the controller to perform performing the following processing:
observing a peak-to-peak voltage between the source power and the bias power; and
adjusting
the source power supplied to the plasma generation source,
the bias power supplied to the stage,
a direct-current voltage applied to an outer peripheral member disposed around the stage, and
an impedance of a filter circuit connected between a source of the direct-current voltage and the outer peripheral member, the source power, the bias power, the direct-current voltage and the impedance being adjustment parameters for controlling a fluctuation width of the observed peak-to-peak voltage.

13. A control method for a plasma processing device that executes plasma processing by supplying source power to a plasma generation source and supplying bias power to a stage on which a substrate to be processed is placed, the control method comprising a controller having a processor and a memory with a computer readable program stored therein that upon execution of the computer readable program by the processor configures the controller to perform performing the following processing:
observing a peak-to-peak voltage between the source power and the bias power; and
adjusting an adjustment parameter for controlling a fluctuation width of the observed peak-to-peak voltage of at least one selected from the following group:
the source power supplied to the plasma generation source,
the bias power supplied to the stage,
a direct-current voltage applied to an outer peripheral member disposed around the stage, and
an impedance of a filter circuit connected between a source of the direct-current voltage and the outer peripheral member.

14. An information processing method comprising a controller having a processor and a memory with a computer readable program stored therein that upon execution of the computer readable program by the processor configures the controller to perform the following processing:
acquiring data indicating a peak-to-peak voltage between a source power supplied to a plasma generation source of a plasma processing device and a bias power supplied to a stage on which a substrate to be processed is placed;
calculating at least one parameter selected from the following group:
the source power supplied to the plasma generation source,
the bias power supplied to the stage,
a direct-current voltage applied to an outer peripheral member disposed around the stage, and
an impedance of a filter circuit connected between a source of the direct-current voltage and the outer peripheral member, the at least one parameter being a parameter for controlling a fluctuation width of the peak-to-peak voltage based on the acquired data; and
controlling the plasma processing device based on the calculated at least one parameter.

15. A plasma processing device comprising:
a stage configured to allow a substrate to be processed to be placed thereon;
an outer peripheral member disposed around the stage;
a first power source configured to supply source power to a plasma generation source;
a second power source configured to supply bias power to the stage;
a third power source configured to apply a direct-current voltage to the outer peripheral member;
a controller configured to:
observe a peak-to-peak voltage between the source power and the bias power; and
adjust
the source power supplied to the plasma generation source,
the bias power supplied to the stage,
the direct-current voltage applied to the outer peripheral member disposed around the stage, and
an impedance of a filter circuit connected between the third power source and the outer peripheral member, the source power, the bias power, the direct-current voltage and the impedance being adjustment parameters for controlling a fluctuation width of the observed peak-to-peak voltage.

16. A plasma processing device comprising:
a stage configured to allow a substrate to be processed to be placed thereon;
an outer peripheral member disposed around the stage;
a first power source configured to supply source power to a plasma generation source;
a second power source configured to supply bias power to the stage;
a third power source configured to apply a direct-current voltage to the outer peripheral member;
a controller configured to:
observe a peak-to-peak voltage between the source power and the bias power; and
adjust at least one selected from the following group:
the source power supplied to the plasma generation source,
the bias power supplied to the stage,
the direct-current voltage applied to the outer peripheral member disposed around the stage, and
an impedance of a filter circuit connected between the third power source and the outer peripheral member, the at least one selected from the group being an adjustment parameter for controlling a fluctuation width of the observed peak-to-peak voltage.

17. An information processing device comprising:
a controller, wherein
the processor is configured to:
acquire data indicating a peak-to-peak voltage between a source power supplied to a plasma generation source of a plasma processing device and a bias power supplied to a stage on which a substrate to be processed is placed,
calculate at least one parameter selected from the following group:
the source power supplied to the plasma generation source,
the bias power supplied to the stage,
a direct-current voltage applied to an outer peripheral member disposed around the stage, and
an impedance of a filter circuit connected between a source of the direct-current voltage and the outer peripheral member, the at least one parameter being a parameter for controlling a fluctuation width of the peak-to-peak voltage based on the acquired data, and
output data including the calculated parameter.

18. The information processing device of claim 17, wherein the controller is further configured to:
collect observed values of the peak-to-peak voltage and the adjustment parameters in seasoning processing executed after the plasma processing device is assembled or after a component including the outer peripheral member is replaced; and
calibrate a model representing a relationship between the peak-to-peak voltage and the adjustment parameters based on the collected observed values,
wherein the seasoning processing involves simulating plasma processing.

19. The information processing device of claim 18, wherein the controller is further configured to: calculate a reference value of the peak-to-peak voltage based on the peak-to-peak voltage observed in a first period in production processing executed after the seasoning processing, and
adjust the adjustment parameters using the calibrated model based on a difference between the calculated reference value and the peak-to-peak voltage observed in a second period after the first period.

20. The information processing device of claim 19, wherein the controller is further configured to: calculate a first reference value of the peak-to-peak voltage based on the peak-to-peak voltage observed in the first period and calculate a second reference value of the peak-to-peak voltage based on the peak-to-peak voltage observed in the second period set independently of the first period, in the production processing executed after the seasoning processing,
adjust the direct-current voltage and the impedance using the calibrated model based on a difference between the calculated first reference value and the peak-to-peak voltage observed in a third period after the first period, and
adjust the source power and the bias power using the calibrated model based on a difference between the calculated second reference value and the peak-to-peak voltage observed in a fourth period after the second period.
